(19) United States
(12) Patent Application Publication
(10) Pub. No.: US 2021/0375951 A1
(43) Pub. Date: Dec. 2, 2021

(54) ARRAY SUBSTRATE, MANUFACTURING METHOD THEREOF, AND DISPLAY PANEL

(71) Applicant: TCL CHINA STAR OPTOELECTRONICS TECHNOLOGY CO., LTD., Shenzhen (CN)

(72) Inventor: Xiaobo HU, Shenzhen (CN)

(73) Assignee: TCL CHINA STAR OPTOELECTRONICS TECHNOLOGY CO., LTD., Shenzhen (CN)

(21) Appl. No.: 16/627,812

(22) PCT Filed: Dec. 23, 2019
(86) PCT No.: PCT/CN2019/127547

§ 371 Date: Dec. 31, 2019

(30) Foreign Application Priority Data
Dec. 13, 2019 (CN) 201911285859.0

(51) Int. Cl. H01L 27/12; G02F 1/1362

(52) U.S. Cl. CPC H01L 27/1222; H01L 27/127; G02F 1/136222

(57) ABSTRACT

The present invention discloses an array substrate, a manufacturing method thereof, and a display panel. The array substrate includes a base substrate and a gate disposed on the base substrate. The gate includes a first side surface near the base substrate and a second side surface opposite to the first side surface. A roughness of the first side surface is greater than a roughness of the second side surface.

### FIELD OF INVENTION

The present invention is related to the field of display technology, and specifically to an array substrate, a manufacturing method thereof, and a display panel.

### BACKGROUND OF INVENTION

With continuous development of production technology of liquid crystal display devices, bezels of the liquid crystal display devices gradually become narrower and even bezel-less. As shown in FIG. 1, a liquid crystal display panel generally includes a color filter (CF) substrate 12 and a thin-film transistor (TFT) substrate 11 disposed opposite to each other. A bezel-less design of the liquid crystal display panel requires a side of the TFT substrate 11 to face outwards in order to bind a printed circuit board.

However, a metal layer (e.g., a gate) in the TFT substrate 11 is not blocked by a light-shielding layer, and ambient light entering the TFT substrate 11 (arrows in FIG. 1 indicate an incident direction of the ambient light) has a large reflectance on a surface of the metal layer, which affects visual effects.

### SUMMARY OF INVENTION

The present invention provides an array substrate to solve a technical problem that a reflectance of ambient light entering the array substrate on a surface of a metal layer is high and affects visual effects.

In a first aspect, the present invention provides an array substrate including:

a base substrate and an array layer disposed on the base substrate;

wherein the array layer includes a gate disposed on the base substrate, the gate includes a first side surface near the base substrate and a second side surface opposite to the first side surface, and a roughness of the first side surface is greater than a roughness of the second side surface.

In some embodiments, a plurality of grooves are disposed on the first side surface of the gate.

In some embodiments, a plurality of protrusions are disposed on a side of the base substrate near the gate, and an orthographic projection of the gate on the base substrate covers an orthographic projection of the plurality of protrusions on the base substrate.

In some embodiments, each of the plurality of protrusions is disposed in each of the plurality of grooves and corresponds to each of the plurality of grooves.

In some embodiments, a shape of each of the plurality of protrusions is same as a shape of each of the plurality of grooves, and a size of each of the plurality of protrusions is same as a size of each of the plurality of grooves.

In some embodiments, the plurality of protrusions are integrally formed with the base substrate.

In some embodiments, a buffer layer is disposed between the base substrate and the gate, the plurality of protrusions are disposed on a side of the buffer layer near the gate, and the plurality of protrusions are integrally formed with the buffer layer.

In some embodiments, a longitudinal section of the first side surface of the gate is a wave shape as a whole.

In a second aspect, the present invention further provides a manufacturing method of the array substrate including the steps of:

S10, providing a base substrate; and

S20, forming an array layer on the base substrate;

wherein the step S20 includes the step of:

S21, forming a gate on a first portion of the base substrate, wherein the gate includes a first side surface near the base substrate and a second side surface opposite to the first side surface, and a roughness of the first side surface is greater than a roughness of the second side surface.

In some embodiments, after the step S10 and before the step S21, the manufacturing method of the array substrate further includes the step of:

S30, patterning a surface of the first portion of the base substrate to form a plurality of protrusions;

wherein the gate is formed on the first portion of the base substrate and is located on a side of the first portion having the plurality of protrusions.

In some embodiments, after the step S10 and before the step S21, the manufacturing method of the array substrate further includes the steps of:

S40, forming a buffer layer on the base substrate; and

S50, patterning a surface of a second portion of the buffer layer to form a plurality of protrusions, wherein the second portion of the buffer layer corresponds to the first portion of the base substrate;

wherein the gate is formed on the surface of the second portion of the buffer layer.

In a third aspect, the present invention further provides a display panel, including:

a color filter substrate and an array substrate;

wherein the color filter substrate is disposed opposite to the array substrate, a liquid crystal layer is disposed between the color filter substrate and the array substrate, and the array substrate includes a base substrate and an array layer; and

wherein the array layer includes a gate disposed on the base substrate, the gate includes a first side surface near the base substrate and a second side surface opposite to the first side surface, and a roughness of the first side surface is greater than a roughness of the second side surface.

In some embodiments, a plurality of grooves are disposed on the first side surface of the gate.

In some embodiments, a plurality of protrusions are disposed on a side of the base substrate near the gate, and an orthographic projection of the gate on the base substrate covers an orthographic projection of the plurality of protrusions on the base substrate.

In some embodiments, each of the plurality of protrusions is disposed in each of the plurality of grooves and corresponds to each of the plurality of grooves.

In some embodiments, a shape of each of the plurality of protrusions is same as a shape of each of the plurality of grooves, and a size of each of the plurality of protrusions is same as a size of each of the plurality of grooves.

In some embodiments, the plurality of protrusions are integrally formed with the base substrate.

In some embodiments, a buffer layer is disposed between the base substrate and the gate, the plurality of protrusions are disposed on a side of the buffer layer near the gate, and the plurality of protrusions are integrally formed with the buffer layer.

In some embodiments, a longitudinal section of the first side surface of the gate is a wave shape as a whole.

A surface of the base substrate or the buffer layer is processed to form the plurality of protrusions on the base substrate or the buffer layer, so that the plurality of grooves formed on the first side surface of the gate matches the plurality of protrusions. The roughness of the first side surface can be increased, which increases diffuse reflection of ambient light irradiating the first side surface and reduces specular reflection of the first side surface. Therefore, a reflectance of the first side surface is reduced, which prevents the ambient light entering the array substrate from having a large reflectance on the first side surface of the gate and affecting visual effects.

### DESCRIPTION OF DRAWINGS

FIG. 1 is a structural diagram of a liquid crystal display panel in the prior art.

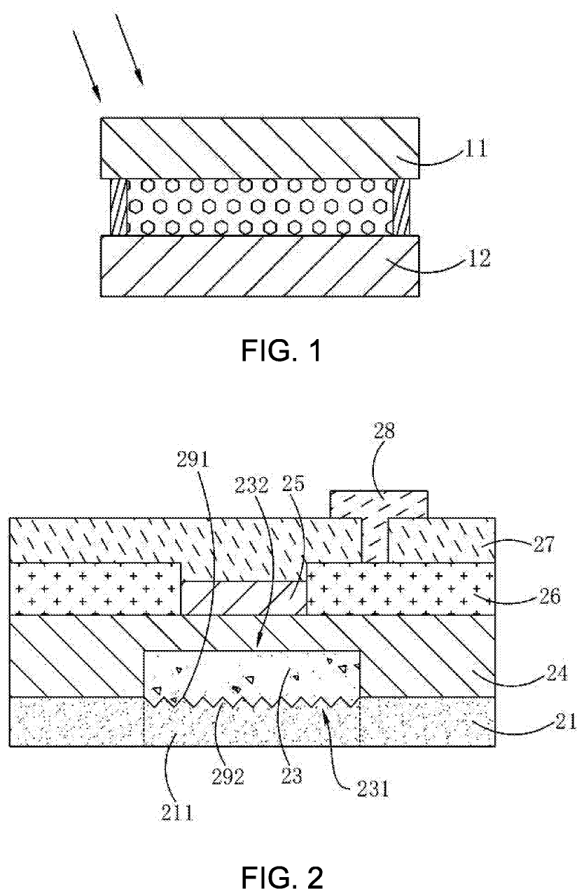

FIG. 2 is a structural diagram of an array substrate in an embodiment of the present invention.

FIG. 3 is a structural diagram of an array substrate in another embodiment of the present invention.

FIG. 4 is a flowchart of step S20 in an embodiment of the present invention.

FIGS. 5 to 10 are structural diagrams of manufacturing processes of the array substrate in an embodiment of the present invention.

FIG. 11 is a structural diagram of a display panel in an embodiment of the present invention.

### REFERENCE SIGNS

thin-film transistor (TFT) substrate 11, color filter (CF) substrate 12, array substrate 20, base substrate 21, first portion 211, buffer layer 22, second portion 221, gate 23, first side surface 231, second side surface 232, gate insulating layer 24, active layer 25, source and drain metal layer 26, passivation layer 27, pixel electrode 28, groove 291, protrusion 292, color filter substrate 30, liquid crystal layer 40, photoresist layer 50, and conductive metal layer 60.

### DETAILED DESCRIPTION OF PREFERRED EMBODIMENTS

The present invention provides an array substrate, a manufacturing method thereof, and a display panel. In order to make purposes, technical solutions, and effects of the present invention clearer and more specific, the present invention is further described in detail below with reference to the accompanying drawings and examples. It should be understood that the specific embodiments described herein are only used to explain the application, and are not used to limit the present invention.

In a current display panel, a metal layer (e.g., a gate) in an array substrate is not blocked by a light-shielding layer, and ambient light entering the array substrate has a large reflectance on a surface of the metal layer, which affects visual effects. The present invention can solve the above problem.

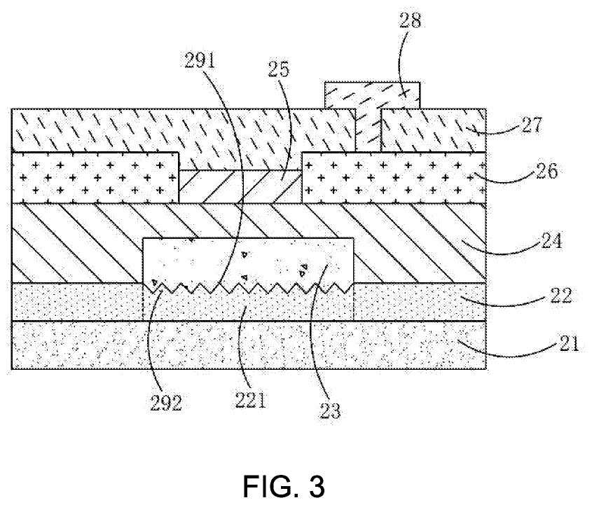

A display panel as shown in FIG. 2, the array substrate 20 includes a base substrate 21 and an array layer disposed on the base substrate 21.

Specifically, the array layer includes a gate 23 disposed on the base substrate 21, a gate insulating layer 24 covering the gate 23, an active layer 25 disposed on the gate insulating layer 24, a source and drain metal layer 26 electrically connected to the active layer 25 and disposed on the gate insulating layer 24, a passivation layer 27 covering the active layer 25 and the source and drain metal layer 26, and a pixel electrode 28 disposed on the passivation layer 27. The pixel electrode 28 is electrically connected to the source and drain metal layer 26 by a bridging hole.

The gate 23 is made of materials including, but not limited to, one or more of copper, molybdenum, aluminum, silver, and titanium.

Specifically, the gate 23 includes a first side surface 231 near the base substrate 21 and a second side surface 232 opposite to the first side surface 231. A roughness of the first side surface 231 is greater than a roughness of the second side surface 232.

It should be explained that the gate 23 is made of metal. For those skilled in the art, the roughness of the first side surface 231 of the gate 23 in the array substrate 20 can be increased by processing the first side surface 231, which increases diffuse reflection of ambient light irradiating the first side surface 231 and reduces specular reflection of the first side surface 231. Therefore, a reflectance of the first side surface 231 is reduced, which prevents the ambient light entering the array substrate 20 from having a large reflectance on the first side surface 231 of the gate 23 and affecting visual effects.

Specifically, a plurality of grooves 291 are disposed on the first side surface 231 of the gate 23, so that the first side surface 231 has an uneven structure, thereby increasing the roughness of the first side surface 231.

The plurality of grooves 291 can be arranged in an order (e.g., an array distribution) or can be arranged in a disorder (e.g., a scattered distribution).

Specifically, a plurality of protrusions 292 are disposed on a side of the base substrate 21 near the gate 23. An orthographic projection of the gate 23 on the base substrate 21 covers an orthographic projection of the plurality of protrusions 292 on the base substrate 21.

It should be explained that the base substrate 21 is a transparent substrate and can be a transparent plastic substrate or a transparent glass substrate. When light passes through a region on the base substrate 21 corresponding to the gate 23, the plurality of protrusions 292 can deflect the light reflected by the plurality of protrusions 292 at large angles, which reduces incident light on the base substrate 21 and prevents the ambient light entering the array substrate 20 from reflecting on the first side surface 231 of the gate 23 to affect the visual effects.

Furthermore, each of the plurality of protrusions 292 is disposed in each of the plurality of grooves 291 and corresponds to each of the plurality of grooves 291.

Furthermore, a shape of each of the plurality of protrusions 292 is same as a shape of each of the plurality of grooves 291, and a size of each of the plurality of protrusions 292 is same as a size of each of the plurality of grooves 291.

The plurality of protrusions 292 and the plurality of grooves 291 can reduce the reflectance of the first side surface 231. Meanwhile, a cooperation of the plurality of protrusions 292 and the plurality of grooves 291 can prevent the plurality of protrusions 292 from increasing an overall thickness of the array layer and can increase adhesion of the gate 23 on the base substrate 21.

In an embodiment, the plurality of protrusions 292 are integrally formed with the base substrate 21.

It should be explained that the base substrate 21 includes a first portion 211 corresponding to the gate 23. The gate 23 is disposed on the first portion 211 of the base substrate 21. The plurality of protrusions 292 extend into the plurality of grooves 291.

The plurality of protrusions 292 can be disposed only on the first portion 211 and is not disposed on rest portions of the base substrate 21, which prevents adverse effects on functions of other film layers.

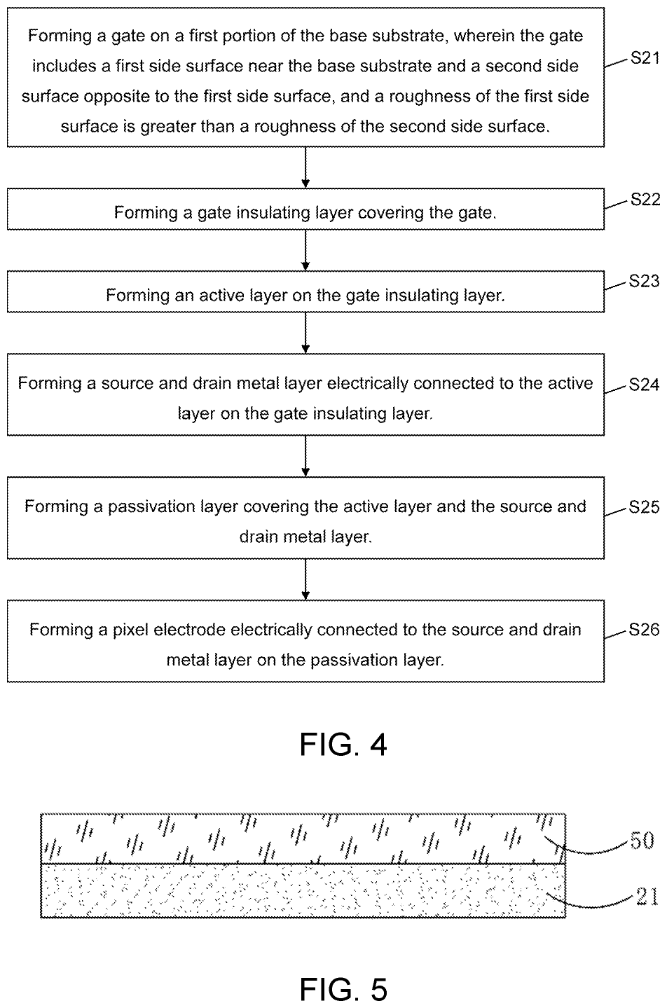

In another embodiment, as shown in FIG. 3, a buffer layer 22 is further disposed between the base substrate 21 and the gate 23. The plurality of protrusions 292 are disposed on a side of the buffer layer 22 near the gate 23. The plurality of protrusions 292 are integrally formed with the buffer layer 22.

The buffer layer 22 is made of materials including, but is not limited to, one or more of silicon nitride, silicon oxide, silicon oxynitride, and polyimide, which prevents a metal in the gate 23 from extending to the base substrate 21.

It should be explained that the buffer layer 22 includes a second portion 221 corresponding to the gate 23. The gate 23 is disposed on the second portion 224 of the buffer layer 22. The plurality of protrusions 292 extend into the plurality of grooves 291.

The plurality of protrusions 292 can be disposed only on the second portion 221 and is not disposed on rest portions of the buffer layer 22, which prevents adverse effects on functions of other film layers.

Specifically, a longitudinal section of the first side surface of the gate is a wave shape as a whole.

It should be explained that a shape of the longitudinal section of the first side surface of the gate can be a continuous wave shape or a discontinuous wave shape.

Based on the above-mentioned array substrate 20, the present invention further provides a manufacturing method of the array substrate 20 including the steps of:

S10, providing a base substrate 21; and

S20, forming an array layer on the base substrate 21.

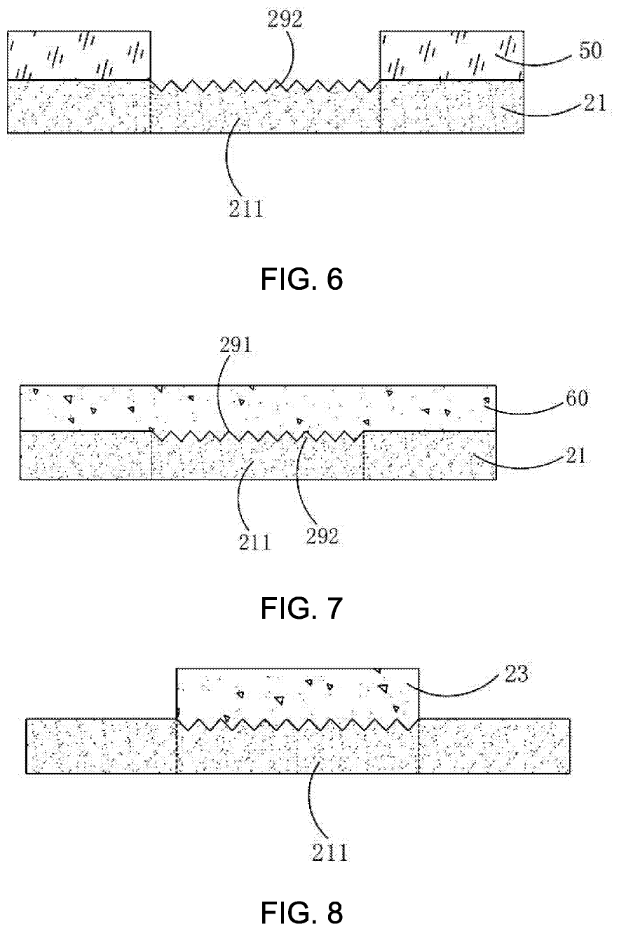

As shown in FIG. 4, the step S20 includes the step of:

S21, forming a gate 23 on a first portion 211 of the base substrate 21, wherein the gate 23 includes a first side surface 231 near the base substrate 21 and a second side surface 232 opposite to the first side surface 231, and a roughness of the first side surface 231 is greater than a roughness of the second side surface 232.

Specifically, the step S20 further includes the steps of:

S22, forming a gate insulating layer 24 covering the gate 23;

S23, forming an active layer 25 on the gate insulating layer 24;

S24, forming a source and drain metal layer 26 electrically connected to the active layer 25 on the gate insulating layer 24;

S25, forming a passivation layer 27 covering the active layer 25 and the source and drain metal layer 26; and

S26, forming a pixel electrode 28 electrically connected to the source and drain metal layer 26 on the passivation layer 27.

In an embodiment, after the step S10 and before the step S21, the manufacturing method of the array substrate 20 further includes the step of:

S30, patterning a surface of the first portion 211 of the base substrate 21 to form a plurality of protrusions 292;

wherein the gate 23 is formed on the first portion 211 of the base substrate 21 and is located on a side of the first portion 211 having the plurality of protrusions 292.

It should be explained that a plurality of grooves 291 matching the plurality of protrusions 292 can be formed on the first side surface 231 of the gate 23 due to a configuration of the plurality of protrusions 292 when forming the gate 23 on the first portion 211. Therefore, the first side surface 231 has an uneven structure, and the roughness of the first side surface 231 is greater than the roughness of the second side surface 232, thereby reducing the reflectance of the first side surface 231.

It should be explained that the first portion 211 of the base substrate 21 can be patterned by processes such as plasma processing, laser, chemical liquid etching, or sandblasting etching.

In another embodiment, after the step S10 and before the step S21, the manufacturing method of the array substrate 20 further includes the steps of:

S40, forming a buffer layer 22 on the base substrate 21; and

S50, patterning a surface of a second portion 221 of the buffer layer 22 to form a plurality of protrusions 292, wherein the second portion 221 of the buffer layer 22 corresponds to the first portion 211 of the base substrate 21;

wherein the gate 23 is formed on the surface of the second portion 221 of the buffer layer 22.

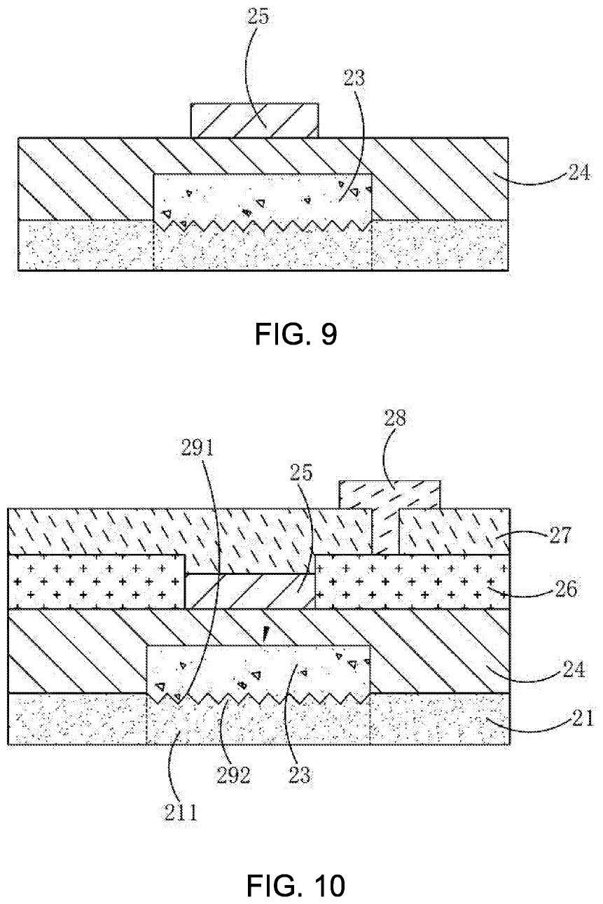

Please refer to FIGS. 5 to 10, which are structural diagrams of manufacturing processes of the array substrate in an embodiment of the present invention.

As shown in FIG. 5, a base substrate 21 is provided. A photoresist layer 50 made of a photoresist material is formed on the base substrate 21.

As shown in FIG. 6, the photoresist layer 50 is processed. A region corresponding to the first portion 211 of the photoresist layer 50 is removed. A surface of the first portion 211 is patterned to form a plurality of protrusions 292.

As shown in FIG. 7, the photoresist layer 50 on the base substrate 21 is removed. A conductive metal layer 60 made of a metal material is formed on the base substrate 21 and covers an entire surface of the base substrate 21. A plurality of grooves 291 matching the plurality of protrusions 292 are formed on a region corresponding to the first portion 211 of a bottom surface of the conductive metal layer 60 when forming the conductive metal layer 60.

As shown in FIG. 8, the conductive metal layer 60 is patterned to form a gate 23 on the first portion 211.

As shown in FIG. 9, a gate insulating layer 24 is formed on the base substrate 21 and covers the gate 23. An active layer 25 is formed on the gate insulating layer 24.

As shown in FIG. 10, after forming a source and drain metal layer 26 electrically connected to the active layer 25 on the gate insulating layer 24, a passivation layer 27 is formed to cover the active layer 25 and the source and drain metal layer 26. A bridging hole is formed on the passivation layer 27, passes through the passivation layer 27, and extends to a surface of the source and drain metal layer 26. A pixel electrode 28 is form on the passivation layer 27 to fill the bridging hole and is electrically connected to the source and drain metal layer 26.

It should be explained that in another embodiment, when forming the plurality of protrusions 292 on the buffer layer 22, a manufacturing method of the array substrate 20 is similar to the above-mentioned manufacturing method of forming the plurality of protrusions 292 on the base substrate 21. The only difference is that the plurality of the protrusions 292 are not formed on the base substrate 21, and after forming the buffer layer 22 on the base substrate 21 and forming the plurality of the protrusions 292 on a surface of the second portion 221 of the buffer layer 22, the gate 23 is formed on the buffer layer 22.

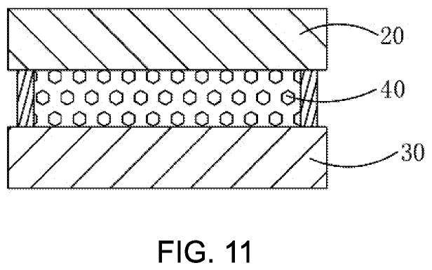

Based on the above array substrate 20, the present invention further provides a display panel. As shown in FIG. 11, the display panel includes a color filter substrate 30 and the array substrate 20 described in any one of the above embodiments. The color filter substrate 30 is disposed opposite to the array substrate 20. A liquid crystal layer 40 is disposed between the color filter substrate 30 and the array substrate 20.

The surface of the base substrate 21 or the buffer layer 22 is processed to form the plurality of protrusions 292 on the base substrate 21 or the buffer layer 22, so that the plurality of grooves 291 formed on the first side surface 231 of the gate 23 matches the plurality of protrusions 292. The roughness of the first side surface 231 can be increased, which increases diffuse reflection of the ambient light irradiating the first side surface 231 and reduces specular reflection of the first side surface 231. Therefore, a reflectance of the first side surface 231 is reduced, which prevents the ambient light entering the array substrate 20 from having a large reflectance on the first side surface 231 of the gate 23 and affecting visual effects.

In the above embodiments, the description of each embodiment has its own emphasis. For a part that is not described in detail in one embodiment, reference may be made to related descriptions in other embodiments.

Although the present invention has been disclosed above by the preferred embodiments, the preferred embodiments are not intended to limit the invention. One of ordinary skill in the art, without departing from the spirit and scope of the present invention, can make various modifications and variations of the present invention. Therefore, the scope of the claims to define the scope of equivalents.

What is claimed is:

1. A array substrate, comprising:
a base substrate and an array layer disposed on the base substrate;
wherein the array layer comprises a gate disposed on the base substrate, the gate comprises a first side surface near the base substrate and a second side surface opposite to the first side surface, and a roughness of the first side surface is greater than a roughness of the second side surface.

2. The array substrate according to claim 1, wherein a plurality of grooves are disposed on the first side surface of the gate.

3. The array substrate according to claim 2, wherein a plurality of protrusions are disposed on a side of the base substrate near the gate, and an orthographic projection of the gate on the base substrate covers an orthographic projection of the plurality of protrusions on the base substrate.

4. The array substrate according to claim 3, wherein each of the plurality of protrusions is disposed in each of the plurality of grooves and corresponds to each of the plurality of grooves.

5. The array substrate according to claim 4, wherein a shape of each of the plurality of protrusions is same as a shape of each of the plurality of grooves, and a size of each of the plurality of protrusions is same as a size of each of the plurality of grooves.

6. The array substrate according to claim 3, wherein the plurality of protrusions are integrally formed with the base substrate.

7. The array substrate according to claim 3, wherein a buffer layer is disposed between the base substrate and the gate, the plurality of protrusions are disposed on a side of the buffer layer near the gate, and the plurality of protrusions are integrally formed with the buffer layer.

8. The array substrate according to claim 3, wherein a longitudinal section of the first side surface of the gate is a wave shape as a whole.

9. A manufacturing method of an array substrate, comprising the steps of:
S10, providing a base substrate; and
S20, forming an array layer on the base substrate;
wherein the step S20 comprises the step of:
S21, forming a gate on a first portion of the base substrate, wherein the gate comprises a first side surface near the base substrate and a second side surface opposite to the first side surface, and a roughness of the first side surface is greater than a roughness of the second side surface.

10. The manufacturing method of the array substrate according to claim 9, wherein after the step S10 and before the step S21, the manufacturing method of the array substrate further comprises the step of:
S30, patterning a surface of the first portion of the base substrate to form a plurality of protrusions;
wherein the gate is formed on the first portion of the base substrate and is located on a side of the first portion having the plurality of protrusions.

11. The manufacturing method of the array substrate according to claim 9, wherein after the step S10 and before the step S21, the manufacturing method of the array substrate further comprises the steps of:
S40, forming a buffer layer on the base substrate; and
S50, patterning a surface of a second portion of the buffer layer to form a plurality of protrusions, wherein the second portion of the buffer layer corresponds to the first portion of the base substrate;
wherein the gate is formed on the surface of the second portion of the buffer layer.

12. A display panel, comprising:
a color filter substrate and an array substrate;
wherein the color filter substrate is disposed opposite to the array substrate, a liquid crystal layer is disposed between the color filter substrate and the array substrate, and the array substrate comprises a base substrate and an array layer; and
wherein the array layer comprises a gate disposed on the base substrate, the gate comprises a first side surface near the base substrate and a second side surface opposite to the first side surface, and a roughness of the first side surface is greater than a roughness of the second side surface.

13. The display panel according to claim 12, wherein a plurality of grooves are disposed on the first side surface of the gate.

14. The display panel according to claim 13, wherein a plurality of protrusions are disposed on a side of the base substrate near the gate, and an orthographic projection of the gate on the base substrate covers an orthographic projection of the plurality of protrusions on the base substrate.

15. The display panel according to claim 14, wherein each of the plurality of protrusions is disposed in each of the plurality of grooves and corresponds to each of the plurality of grooves.

16. The display panel according to claim 15, wherein a shape of each of the plurality of protrusions is same as a shape of each of the plurality of grooves, and a size of each of the plurality of protrusions is same as a size of each of the plurality of grooves.

17. The display panel according to claim 14, wherein the plurality of protrusions are integrally formed with the base substrate.

18. The display panel according to claim 14, wherein a buffer layer is disposed between the base substrate and the gate, the plurality of protrusions are disposed on a side of the buffer layer near the gate, and the plurality of protrusions are integrally formed with the buffer layer.

19. The display panel according to claim 14, wherein a longitudinal section of the first side surface of the gate is a wave shape as a whole.
